(19) United States
(12) Patent Application Publication
(10) Pub. No.: US 2013/0032432 A1
(43) Pub. Date: Feb. 7, 2013

(54) Slip Resistant Cover For Portable Electronics

(71) Applicant: Mark R. Slotta, Cary, NC (US)

(72) Inventor: Mark R. Slotta, Cary, NC (US)

(21) Appl. No.: 13/565,529

(22) Filed: Aug. 2, 2012

Related U.S. Application Data
(60) Provisional application No. 61/529,072, filed on Aug. 30, 2011.
(60) Provisional application No. 61/514,170, filed on Aug. 2, 2011.

(51) Int. Cl. H05K 5/03; H05K 5/00; G10K 11/00

(52) U.S. Cl. 181/199; 361/679.01; 312/223.1

(57) ABSTRACT

A cover for an electronic device includes a back panel adapted to substantially cover a back face of the electronic device. The back panel includes a friction-reducing treatment on at least a portion of the panel that is in contact with the back face. The cover also includes a restraining portion adapted to be disposed against an opposed face of the electronic device. The restraining portion is attached to the back panel by a side member and the restraining portion adapted to maintain the back panel in an installed position relative to the back face.

### CROSS-REFERENCE TO RELATED APPLICATIONS

This application claims the benefit of U.S. Provisional Application No. 61/514,170, filed Aug. 2, 2011 and the benefit of U.S. Provisional Application No. 61/529,072, filed Aug. 30, 2011, the disclosures of which are incorporated herein by reference.

### BACKGROUND OF THE INVENTION

This invention relates in general to covers for portable electronics. Portable electronics are becoming increasingly common and are increasing in available functions. Portable electronics include devices such as cellular phones, media players, video game systems, electronic book readers, global positioning system (GPS) receivers, notebook computers, netbook computers, IPAD®, SLATE®, and other devices. Many of these devices have multiple functions, and are used in a variety of locations under a variety of conditions.

### SUMMARY OF THE INVENTION

This invention relates to a cover for an electronic device. The cover includes a back panel adapted to substantially cover a back face of the electronic device. The back panel includes a friction-reducing treatment on at least a portion of the panel that is in contact with the back face. The cover also includes a restraining portion adapted to be disposed against an opposed face of the electronic device. The restraining portion is attached to the back panel by a side member and the restraining portion adapted to maintain the back panel in an installed position relative to the back face.

Various aspects of this invention will become apparent to those skilled in the art from the following detailed description of the disclosed embodiments, when read in light of the accompanying drawings.

### BRIEF DESCRIPTION OF THE DRAWINGS

FIG. 1 is a perspective view, taken from the front, of a cover for an electronic device.

FIG. 2 is an elevational view, taken from the front, of the device that the cover of FIG. 1 is adapted to fit.

FIG. 3 is an elevational view, taken from the rear, of the device of FIG. 2.

FIG. 4 is a perspective view, taken from the side, of the device of FIG. 2.

FIG. 5 is a cross-sectional view, taken along the line 5-5 of FIG. 1.

FIG. 6 is a perspective view, taken from behind, of the cover of FIG. 1.

FIG. 7 is a detailed perspective view of the call out 7 on FIG. 6.

FIG. 8 is a detailed elevational view of the call out 7 on FIG. 6.

FIG. 9 is a cross sectional view taken along the line 9-9 of FIG. 8.

FIG. 10 is a front plan view of an alternative cover that includes an interior texture.

FIG. 11 is a close-up view of the interior texture of the alternative cover of FIG. 10.

FIG. 12 is a cross-sectional view taken along the line 12-12 of FIG. 11.

FIG. 13 is a perspective view of the alternative cover of FIG. 11 installed on a device that includes a movable cover.

FIG. 14 is a perspective view of similar to that shown in FIG. 13, with the movable cover illustrated in a use position.

FIG. 15 is a cross-sectional view taken along the line 15-15 of FIG. 10.

FIG. 16 is a cross-sectional view taken along the line 16-16 of FIG. 10, illustrating an alternative hinge protection.

FIG. 17 is a cross-sectional view taken along the line 17-17 of FIG. 13.

FIG. 18 is a cross-sectional view taken along the line 18-18 of FIG. 10.

FIG. 19 is a cross-sectional view taken along the line 19-19 of FIG. 10.

### DETAILED DESCRIPTION OF THE PREFERRED EMBODIMENTS

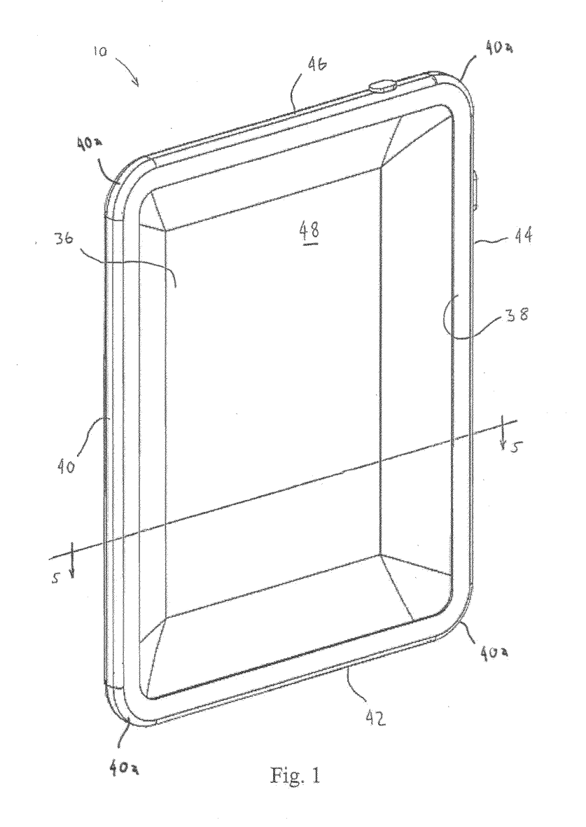

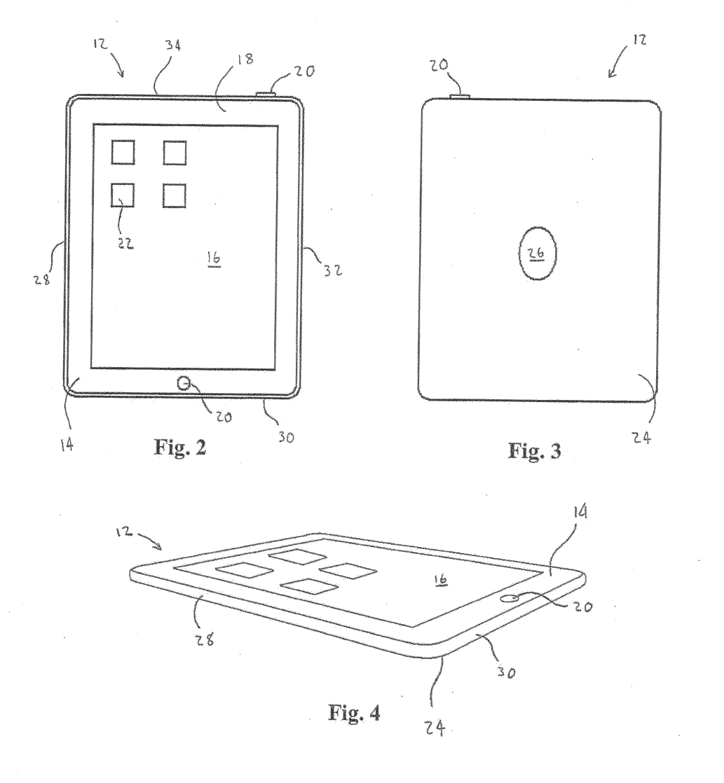

Referring now to the drawings, there is illustrated in FIG. 1, a cover 10 for a device, indicated in FIG. 2 at 12. The illustrated device 12 is a touch-screen, tablet style, IPAD® manufactured by APPLE® and the illustrated cover 10 will be described in reference to the particular features of the illustrated device 12. However, it should be appreciated that the device 12 may be any other desired device, including an electronic device such as a cellular phone, a media player, an electronic book reading device, a video game system, a GPS receiver, a laptop computer, a notebook computer, a netbook computer, or other desired electronic device, and that particular shape, dimensions, and other features of the cover 10 could be changed from those illustrated in order to accommodate some other electronic device. Further, it should also be appreciated that the cover 10 may be used on items other than electronic devices. The cover 10 may be used on any desired item that would benefit from the slip resistant and protective characteristics of the cover 10. This can include items such as coffee mugs, tools, writing instruments, glasses cases, sporting equipment, hunting and camping gear, or fishing gear and tackle boxes.

In continued reference to FIG. 2, the device 12 includes a front face 14 that includes a touch screen 16 and a bezel 18. The device 12 also includes controls 20. The controls 20 may include buttons, switches, slides, or other desired interface devices. Typically, a user interacts with the device 12 using the controls 20 and by interacting with the touch screen 16 and icons 22 on the touch screen 16. It should be appreciated that the device 12 may also include input/output (I/O) ports, such as universal serial bus (USB) jacks, headphone jacks, slots for subscriber identity module (SIM) cards, slots for removable memory, infrared transmitters or receivers, or other desired I/O ports. Additionally, the device 12 may include features such as cameras, speakers, microphones, or other desired features. The device 12 may also include ventilation ports.

Referring to FIG. 3, a back face 24 of the device 12 is shown. It should be appreciated that the back face 24 of the device 12 is a marked face, and includes a trademark 26. Referring to FIG. 4, a perspective view of the device 12 is shown. A first device side 28 and a device bottom 30 are visible. As seen in reference to FIG. 2, the device 12 also includes a second device side 32 and a device top 34. It should be appreciated that although the device 12 has been described generally as a six-sided box, the device 12 includes various curved surfaces and beveled edges between the various sides.

Referring back to FIG. 1, the cover 10 includes a back panel 36. The back panel 36 is adapted to cover and substantially conform to the back face 24 of the device 12 when the cover 10 is placed in an installed position on the device 12. The cover 10 also includes a restraining portion 38. The restraining portion 38 is adapted to substantially conform to a portion of the bezel 18 of the device 12 when the cover 10 is placed in the installed position. The back panel 36 and the restraining portion 38 are connected by a first cover side 40 a cover bottom 42, a second cover side 44, and a cover top 46; each of these portions is a side member that provides protection to the sides of the electronic device 12. Since the cover 10 has a side member on each side, the cover 10 provides protection to all sides of the device 12 while keeping the touch screen 16 accessible. The side member of the cover 10 defines four corners 40a. The cover 10 may have an increased thickness as the corners 40a, in order to provide increased protection if the device 12 is dropped on a corner, since that sort of fall may be more likely to damage the device 12. It should be appreciated that although the cover 10 has been described generally as including six parts, the cover 10 is adapted to conform to the surfaces, curves, chamfers, and contours of the device 12 when the cover 10 is in the installed position. The shape and dimensions of the cover 10 can be selected to conform to the shape and dimensions of the device 12 so that the cover 10 will fit snuggly on the device 12, while still being easy for the user to install the cover 10 on the device 12.

The cover 10 is made of a thermoplastic elastomer (TPE). The cover 10 may be made of some other resilient material, such as silicone or other desired resilient materials. Further, it should be appreciated that the cover 10 or parts of the cover 10 may be made of non-resilient materials, if desired. It should also be appreciated that the cover 10 may be made of a combination of materials, if desired. The illustrated cover 10 is made of a material that is transparent. This allows the device 12 to be seen and identified when the cover 10 is in the installed position. Alternatively, the cover 10 or portions of the cover 10 may be translucent or opaque, if desired. The cover 10 may be made in a variety of colors, and may include patterns, designs, text, or any other desired aesthetic feature.

The cover 10 is adapted to be placed in the installed position on the device 12 by situating an interior surface 48 of the back panel 36 adjacent to the back face 24 of the device 12. The restraining portion 38 is stretched over the sides of the device 12 so that the restraining portion 38 is adjacent to the bezel 18 of the device 12. The restraining portion 38 acts to maintain the back panel 36 in the installed position. It should be appreciated that it is not necessary for the device 12 to have a bezel 18 in order for the cover 10 to be used, and if the device 12 does not have a bezel, the cover 10 may conform to a portion of the screen 16, the cover 10 may engage with two or more of the first device side 28, the device bottom 30, the second device side 32 and the device top 34, for example. It should also be appreciated that the cover 10 may be adapted to be installed on the device 12 in other ways, if desired. For instance, the cover 10 may be held in place by adhesives, snaps, electrostatic force, or by other fasteners or attachment mechanisms. Alternatively, the cover 10 may be held in place by being engaged by a portion of the device 12, for example, by being held by a battery compartment cover.

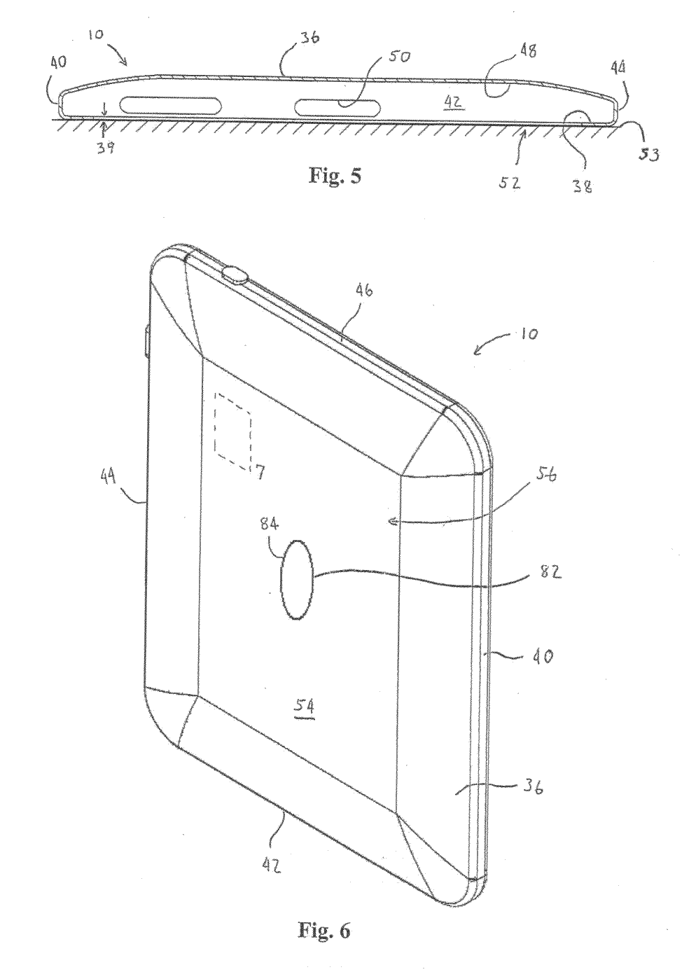

The cover 10 is adapted to fit snuggly on the device 12. The cover 10 includes access openings 50 (shown in FIG. 5) to allow the user to access the controls 20 when the cover 10 is in the installed position. It should be appreciated that the cover 10 may not need an opening 50 for each control 20, depending on the type of control. For example, a push-button may be operable through the cover 10 without the need for an opening. The cover 10 may also include openings that correspond to the various I/O ports, charging ports, speakers, microphones, additional features, and ventilation openings on the device 12.

Referring to FIG. 5, the restraining portion 38 defines a screen opening, indicated at 52. The screen opening 52 allows the user to access and interact with the touch sensitive screen 16 of the device 12 when the cover 10 is in the installed position. It should be appreciated that the screen opening 52 may include a screen protective layer (not shown), such as a plastic sheet. Alternatively, the screen protective layer may be made of the same material as the restraining portion, if desired. It should also be appreciated that the cover 10 may not include the screen opening 52 if the device 12 does not include a touch sensitive screen 16. The restraining portion 38 includes a thickness 39. It should be appreciated that when the device 12 is placed on a support surface 53 with the touch sensitive screen 16 facing the support surface 53, the restraining portion 38 will be in contact with the support surface 53 and there will be a space between the screen 16 and the support surface 53. Thus, the touch sensitive screen 16 will not be in contact with the support surface 53 which helps protect the touch sensitive screen 16 from damage. Additionally, the restraining portion 38 can provide a higher coefficient of friction when in contact with the support surface 53 than the bare device 12 would have. This can increase the frictional force between the device 12 and the support surface 53, and can help make the device 12 less likely to move. As a result, the device 12 is less likely to undergo undesired movement when a table, vehicle, or other support surface 53 is moved, either intentionally or unintentionally.

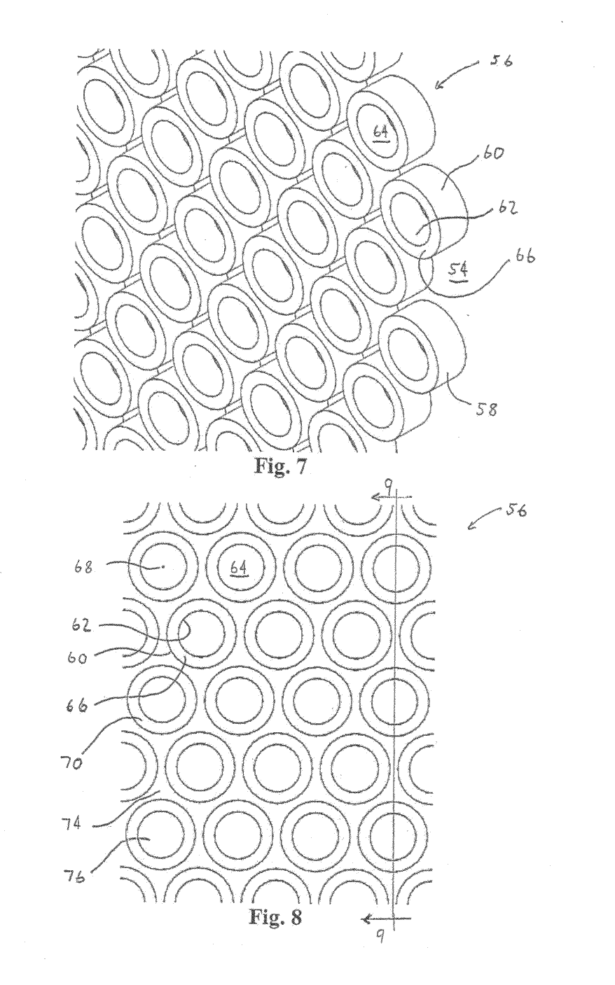

Referring now to FIG. 6, a perspective view, taken from behind, of the cover 10 is shown. The back panel 36 includes an outer surface 54 that has a textured portion, indicated at 56. The textured portion 56 is provided to increase the frictional force between the cover 10 and any other surface that it is in contact with. This allows the device 12 to be placed in a position on a surface such as a table or vehicle dash board and makes the device less likely to slide away from that position. As a result, the device 12 is less likely to undergo undesired movement when a table, vehicle, or other support surface is moved, either intentionally or unintentionally. Additionally, the textured portion 56 increases the coefficient of friction between the cover 10 and the hand of the user when holding the device 12. This reduces the amount of finger tension required to hold the device 12 and may make it more comfortable for the user to hold the device 12. This also makes it less likely that the user will accidentally drop the device 12.

Referring to FIG. 7, a detailed perspective view of a part of the textured portion 56 is shown. The textured portion 56 includes a series of projections 58 that extend from the outer surface 54 of the back panel 36. The projections 58 have exterior side walls 60 that are substantially transverse to the outer surface 54 of the back panel 36. Alternatively, the projections 58 may have exterior side walls 60 with other desired orientations. The projections 58 also include interior side walls 62 that define voids 64. The interior side walls 62 are substantially transverse to the outer surface 54 of the back panel 36. Alternatively, the interior side walls 62 may have other desired orientations. The projections 58 include an outer surface 66. The outer surface 66 connects the exterior side wall 60 and the interior side wall 62. Alternatively, the projection 58 may not have an outer surface 66, and the exterior side wall 60 and the interior side wall 62 may meet. Additionally, it should be appreciated that one or both of the exterior side wall 60 and the interior side wall 62 may be curved, and the outer surface 66 may be part of either the exterior side wall 60 or the interior side wall 62.

Referring now to FIG. 8, a detailed elevational view of the textured portion 56 is shown. The view is taken looking perpendicular to the outer surface 54 of the back panel 36. The exterior side wall 60 has an outer cross sectional shape that is substantially circular. The exterior side wall 60 has a diameter of approximately 0.5 mm. Also, the interior side wall 62 has an inner cross sectional shape that is substantially circular. The interior side wall 62 has a diameter of approximately 0.3 mm. The outer cross sectional shape and the inner cross sectional shape are substantially coaxial, having a common axis 68. The projections 58 include a projection body 70. The projection body 70 is the material of the projection 58 between the exterior side wall 60 and the interior side wall 62. The projection body 70 has a toroid shape. Alternatively, the outer cross sectional shape and the inner cross sectional may be other than substantially coaxial. Also, the outer cross sectional shape and the inner cross sectional shape may be other than substantially circular. Additionally, the projections 58 may have a different size from that shown. It should be appreciated that the shape of the projection body 70 will vary depending on the orientation of the exterior side wall 60, the interior side wall 62 and the outer surface 66.

The projections 58 that comprise the textured portion 56 are arranged in a series of staggered rows. The axes 68 of adjacent projections 58 are spaced by approximately 0.5 mm. Alternatively, adjacent axes 68 may be spaced by a different amount. It should be appreciated that the spacing may be varied based on the size and weight of the device 12, based on aesthetic considerations, or for other desired reasons. The projections 58 may be arranged in a different pattern from that shown, if desired. The textured portion 56 includes an open texture 74. The open texture 74 includes the area between adjacent projections 58. The textured portion 56 also includes a closed texture 76. The closed texture 76 includes the voids 64.

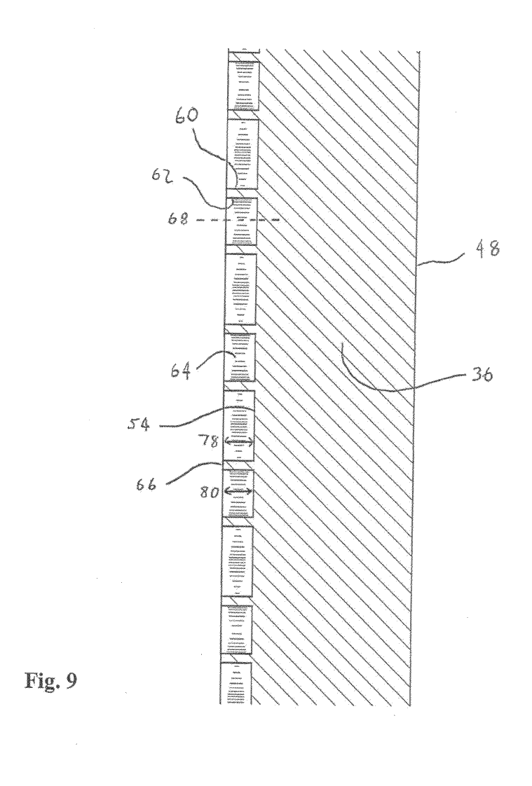

Referring now to FIG. 9, a cross sectional view taken through the line 9-9 of FIG. 8 is shown. The outer surface 66 is substantially parallel to the outer surface 54 of the back panel 36. Alternatively, the outer surface 66 may be other than parallel to the outer surface 54 of the back panel 36. The projections 58 have a projection height 78 from the outer surface 66. The voids 64 have a void depth 80. The projection height 78 and the void depth 80 are approximately 0.2 mm. Alternatively, the projection height 78 and the void depth 80 may be any other desired size. The projection height 78 and the void depth 80 are approximately the same size; however, they may be different sizes, if desired.

The configuration of the projections 58 allows the voids 64 to act as suction cups. This may help to increase the coefficient of friction between the cover 10 and the support surface. Alternatively, the projections 58 may include cuts in the outer surface 66 or channels through the projection body 70 in order to allow fluid communication between the closed texture 76 and the open texture 74.

Although the illustrated embodiment of the textured portion 56 shows all of the projections 58 having the same configuration, it should be appreciated that the projections 58 may have different configurations on different parts of the textured portion 56. This may be done to provide variations in appearance, variations in friction, variations in feel, or for any other desired reason.

Referring back to FIG. 6, the textured portion 56 covers substantially the entire outer surface 54 of the back panel 36. Alternatively, the textured portion 56 may cover less than substantially the whole back panel 36. This may be done for aesthetic purposes, to provide a different feel for the user holding the device 12, or for other desired reasons. The cover 10 also includes a window 82. This window 82 is positioned on the cover 10 to correspond to the location of the trademark 26 on the back face 24 of the device 12 when the cover 10 is installed on the device 12. The window 82 is a visually transparent portion of the cover 10 that is adapted to allow the trademark 26 to be visible when the cover 10 is in the installed position on the device 12. The window 82 is made of the same material as the back panel 36. Because the material is transparent, the trademark 26 is visible through the window 82. It should be appreciated that the window 82 is a portion of the back panel 82 that is not covered by the textured portion 56. It should be appreciated that the window 82 may, however, include texture, if desired. Alternatively, the window 82 may be made of different material than the back panel 36. For example, if the back panel 36 is tinted or colored, the window may be made of a non-colored, transparent material, if desired. Additionally, the window 82 may comprise a hole or opening through the back panel 36.

The window 82 has a shape or outline 84. The shape 84 substantially corresponds to the shape of the trademark 26. This allows the trademark 26 to be visible through the window, and allows the textured portion 56 to outline the trademark 26. This may assist the user in properly positioning the cover 10 on the device 12, as the user can align the window 82 with the trademark 26 to help determine that the cover 10 is being properly placed in the installed position. Alternatively, the shape 84 may have some other configuration than substantially corresponding to the shape of the trademark 26, if desired. For example, the shape 84 may be larger than the shape of the trademark 26, allowing the trademark 26 and additional portions of the device to be visible through the window 82. Alternatively, the shape 84 may be smaller than the shape of the trademark 26, allowing only part of the trademark 26 to be visible through the window 82.

It should be appreciated that the window 82 may be positioned on the cover 10 to allow portions of the device 12 other than the trademark 26 to be visible. For example, the cover 10 may include a window that corresponds to instructions, identifying information, or screens on the device 12. Additionally, it should be appreciated that the cover 10 may include more than one window 82, if desired.

The cover 10 has been described with the textured portion 56 on the back panel 36, which is on the opposite side of the device 12 from the touch screen 16 when the cover is installed. It should be appreciated that it may be desirable to have texture on different surfaces, including, for example, the face of the restraining portion 38, the first cover side 40, the cover bottom 42, and the second cover side 44. This additional texture can allow the user to place the device 12 in a variety of positions and taking advantage of the improved slip resistant characteristics of the cover 10 provided by the texture. Also, it should be appreciated that on different devices it may be desirable to have texture on different surfaces or more surfaces. For example, on a laptop computer or a portable digital versatile disk (DVD) player, it may be desirable to have a textured surface on the bottom of the unit, in order to help prevent movement of the device while in use. Further, on a digital camera, it may be desirable to have a textured surface on the bottom of the camera, as well as on the back of the camera, in order to help prevent movement of the camera from a position that the user may set it down on a surface.

Although the cover 10 has been described as being placed on the device 12, it should be appreciated that the cover 10 may be installed on a support surface in order to help prevent the movement of articles placed on that support surface. For example, portions of a dash board of a vehicle, a table, or a work bench may include the textured portion 56. This would help to prevent undesired movement of articles placed on the surface of the dash board, the table or the work bench.

The cover 10 has been described as including the textured portion 56 in order to increase the coefficient of friction between the cover 10 and the support surface. It should be appreciated, however, that the cover 10 can increase the coefficient of friction between the device 12 and the support surface without including the textured portion 56 on the cover 10. Electronic devices, such as the device 12, typically have an outer shell that is made of metal or hard plastic in order to protect the components of the device 12. The shell will typically have a relatively low coefficient of friction on surfaces such as wood, plastic, metal and glass. As a result, the device 12 can easily slide or shift when placed on a table, counter top, desk, or other common support surface. Additionally, the smooth shell can make the device 12 more difficult to hold, particularly with one hand. The TPE material that the cover 10 is made of typically has a higher coefficient of friction that the shell of the device 12. Thus, even without the textured portion 56, the cover 10 can help make the device 12 less likely to undergo undesired movement and make the device 12 easier to hold.

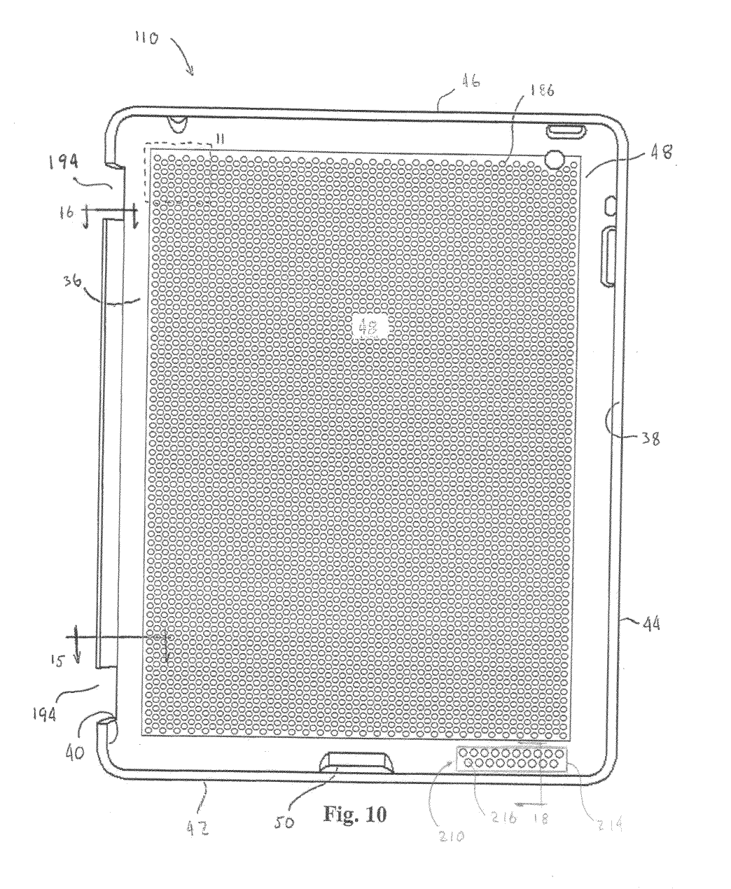

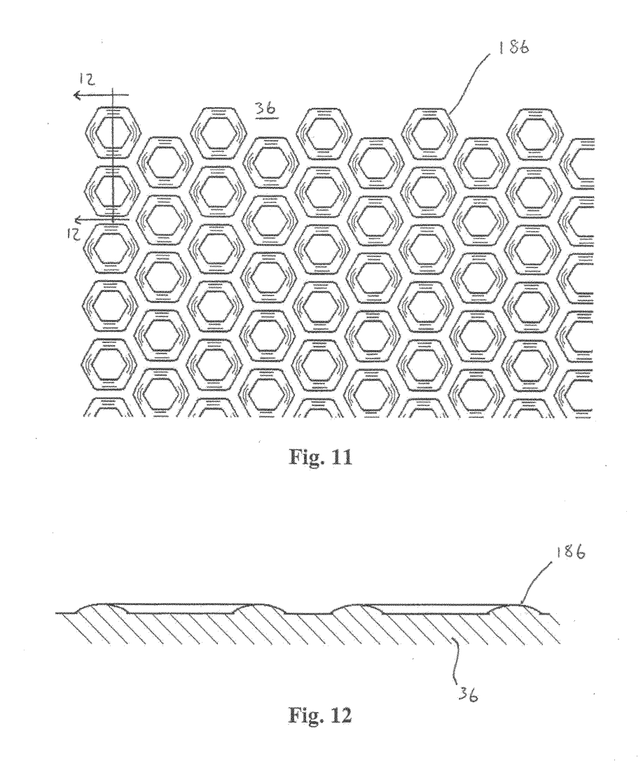

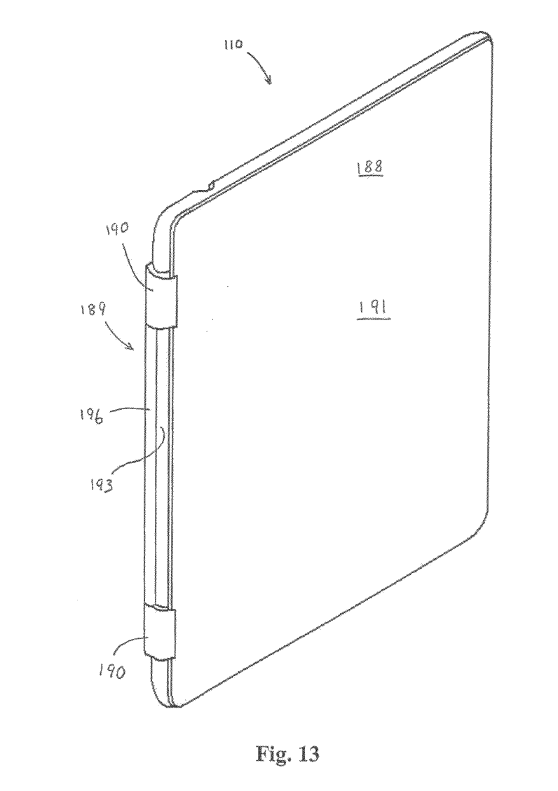

Referring now to FIG. 10, a front plan view of an alternative cover 110 is shown. The alternative cover 110 has a different shape and dimensions from the cover 10, since the alternative cover 110 is designed to fit an IPAD 2 manufactured by APPLE® (a device 112 shown in FIG. 13). The alternative cover 110 includes many features similar to the cover 10, and similar features are identified by the same number. It should be appreciated that while the illustrated alternative cover 110 is designed to fit a particular electronic device, the alternative cover 110 may be designed to fit other electronic devices or non-electronic devices, and the features of the alternative cover 110 may be incorporated into over covers, if desired.

The alternative cover 110 includes a friction-reducing treatment 186 on a portion of the interior surface 48. The friction-reducing treatment 186 serves to reduce the amount of friction between the alternative cover 110 and the device 112. Reducing the amount of friction makes it easier for the user to place the alternative cover 110 in an installed position on the device 112 by making it easier for the user to adjust the position of the back panel 36 relative to the back face 24 of the device 112. This makes it easier for the user to move the alternative cover 110 relative to the device 112 during installation, so that the alternative cover 110 does not have to be in a particular position relative to the device 112 when the two are first brought into contact. Additionally, the reduced friction makes it easier for the user to smooth out any portions of the back panel 36 that are excessively stretched or compressed after the alternative cover 110 has been installed on the device 112.

The illustrated friction-reducing treatment 186 is an interior texture. The interior texture serves to reduce the amount of the surface area of the interior surface 48 that is in contact with the back face 24 of the device 112. The illustrated interior texture covers substantially the whole interior surface 48, but the interior texture may cover less than the whole interior surface 48, if desired.

Referring to FIG. 11, a close up view of a portion of the interior texture is shown. The illustrated interior texture 186 consists of a pattern of regular hexagons. It should be appreciated that the interior texture may have an appearance or shape other than the regular hexagons, if desired. For example, the interior texture 186 may include other geometric shapes, comprise apparently random patterns, be decorative, or include text elements. It should be appreciated that the interior texture 186, or portions of the interior texture 186, may be made to be visible through the back panel 36, if desired.

Referring to FIG. 12, a cross-section of a portion of the back panel 36 is shown, taken through the interior texture 186. The hexagons comprising the illustrated interior texture are round-topped, and are molded of the same material as the rest of the back panel 36. However, the interior texture 186 may be molded separately from the back panel 36, or may be made from a different material than the back panel 36, if desired. Additionally, the friction-reducing treatment 186 may comprise depressions or voids in the back panel 36, rather than the raised texture illustrated. The friction-reducing treatment 186 may alternatively comprise a layer of material on the interior surface 48 that serves to reduce the amount of friction between the device 112 and the alternative cover 110, or the friction-reducing treatment 186 may comprise discrete pieces of material, such as beads, attached to or embedded in portions of the back panel 36.

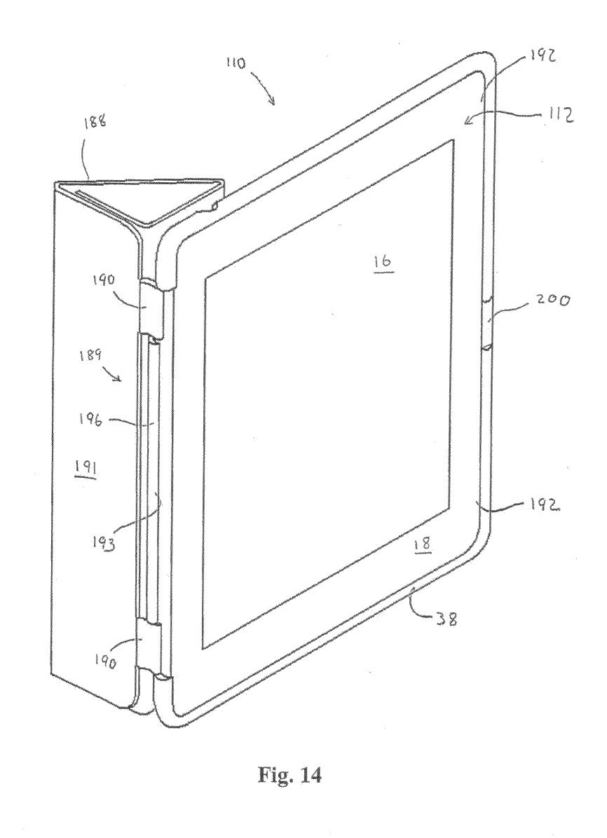

Referring now to FIGS. 13 and 14, perspectives view of the alternative cover 110 when installed on the device 112 is shown. In the embodiment shown, the device 112 includes a folding, hinged cover 188. The hinged cover 188 is a movable cover, and can be moved from a protective position shown in FIG. 13, in which a cover panel 191 covers to the touch screen 16, to a use position shown in FIG. 14, in which the hinged cover 188 may be used to support the device 112 in a use position. The hinged cover 188 may, for example, be the Smart Cover on an iPad 2 manufactured by Apple®. The Smart Cover is configured to be movable into a variety of positions, in order to allow the user to prop the device 112 in different positions for viewing, typing, or comfortable holding. The hinged cover 188 is attached to the device 112 by a hinge assembly indicated generally at 189. The hinge assembly 189 includes two hinges 190 that are attached to the cover panel 191 and a hinge bar 193. The hinge bar 193 is able to be temporarily attached to the device 112 using magnets.

The hinged cover 188 also communicates magnetically with the device 112, and the device 112 can change its operation based on the position of the hinged cover 188. For example, device magnets located in the area indicated by 192 can be used to detect when the hinged cover 188 is in the protective position on the touch screen. The device 112 can then turn itself on from a standby mode when the hinge cover 188 is moved off the touch screen 16. The hinged cover 188 provides additional functionality for the user of the device 112, and it is desirable to maintain that functionality when using the alternative cover 110.

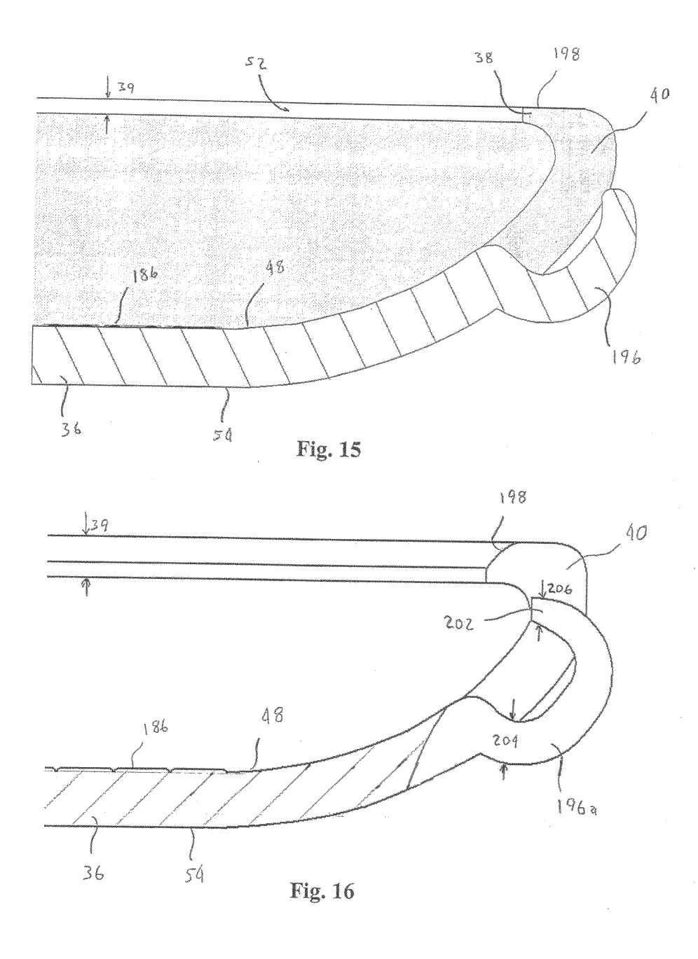

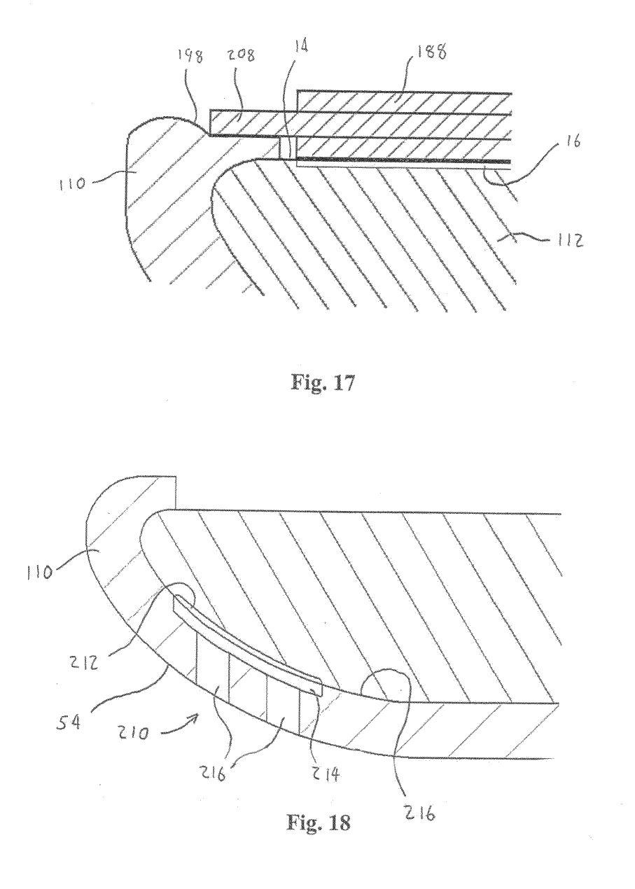

The alternative cover 110 is a stationary cover that accommodates the hinged cover 188. The alternative cover 110 includes hinge openings 194 (best seen in FIG. 10) that correspond to the locations of the hinges 190. The hinge openings 194 allow the hinges 190 and the hinged cover 188 to move through their normal range of motion. The alternative cover also includes a hinge protection 196 that serves to help protect the hinge bar 193. The hinge protection 196 extends from the back panel 36 and is made of the same material as the back panel. As best seen in the cross-section in FIG. 15, the hinge protection 196 conforms to the shape of and encloses a portion of the hinge bar 193.

Referring back to FIG. 10, it can be seen that the hinge protection 196 is situated so that the hinge openings 194 are located at opposed ends of the hinge protection. It should be appreciated that the specific configuration of the hinge openings 194 and the hinge protection 196 can be determined based on the configuration of the device 112 and its accessories. It should also be appreciated that the hinge protection 196 does not need to be continuous between the hinge openings 194.

Referring to FIG. 16, a cross-sectional view of an alternative hinge protection 196a is shown. The alternative hinge protection 196a extends from the back panel 36 to a distal end 202. The distal end 202 of the alternative hinge protection 196a will be in contact with the electronic device 112 when the alternative cover 110 is in the installed position. As a result, the alternative hinge protection 196a covers the entire hinge bar 193. The alternative hinge protection 196a includes a base thickness 204 near the back panel and a distal thickness 206 at the distal end 202. The base thickness 204 is greater than the distal thickness 206, and provides the alternative hinge protection 196a with increased rigidity. This allows the alternative hinge protection 196a to resist a greater amount of force before deforming. As a result, the alternative hinge protection 196a is better able to help maintain the proper position of the hinged cover 188 on the device 112 by helping to prevent unwanted movement of the hinge bar 193 relative to the device 112.

As can also be seen in reference to FIG. 16, the restraining portion 38 of the alternative cover 110 defines a raised surface 198 that is spaced apart from the front face 14 of the electronic device 112. As shown in FIG. 16, the hinged cover 188 includes an edge lip 208. When the hinged cover 188 is in the protective position, a portion of the movable cover 188 is in contact with the touch screen 16 of the electronic device 112, and a portion of the edge lip 208 is in contact with the raised surface 198. It should be appreciated that the raised surface 198 may be made farther away from the device 112 in order to prevent the hinged cover 188 from contacting the touch screen 16, if desired. The contact between the hinged cover 188 and the alternative cover 110 forms a seal that helps prevent dust and other particulates from coming into contact with the touch screen 16. The alternative cover 110 may include an optional opening assist 200, shown in FIG. 14. The opening assist 200 may be useful when, as in the illustrated embodiment, the hinged cover 188 includes a mechanism to help restrain it in the protective position. The opening assist 200 aids the user in moving the hinged cover 188 away from the protective position. The illustrated opening assist 200 is a cut out that allows space for the user to insert a finger nail between the alternative cover 110 and the hinged cover 188.

The restraining portion 38 of the alternative cover 110 allows the device magnets 192 to detect the hinged cover 188. This permits the alternative cover 110 to be installed on the device 112, while still allowing the hinged cover 188 to be used with the device 112 without impairing its functionality. In the illustrated embodiment, the device magnets 192 are able to detect the hinged cover 188 because the restraining portion 38 is thin enough to not interfere with the magnetic communication. It should be appreciated that the alternative cover 110 may include additional features to facilitate communication between the device 112 and the hinged cover 188, if desired. For example, if the device 112 and the hinged cover 188 physically engage or latch to each other, then an opening may be included in the alternative cover 110, or if the device 112 and the hinged cover 188 communicate electronically, then electrically conductive elements may be included in the alternative cover 110. It should be appreciated that the specific features incorporated into the alternative cover necessary to allow communication between the device 112 and the hinged cover 188 will vary depending on how the device 112 and the hinged cover 188 are designed to communicate with each other. It should also be appreciated that the alternative cover 110 may include features to allow or facilitate communication between the device 112 and accessories or peripherals other than or in addition to the hinged cover 188. The specific features of the alternative cover 110 that are necessary to allow or facilitate such communication will depend on the specific design of the device 112 and the accessory or peripheral in question.

As seen in FIG. 15, the alternative cover 110 encloses the sides of the electronic device 112. Thus, in any orientation, the alternative cover 110 is situated between the electronic device 112 and a support surface. This also means that if the electronic device 112 is dropped, the alternative cover 110 will be able to absorb some of the force of the impact. It should be appreciated that the alternative cover is relatively thick, compared to some existing covers such as relatively hard polymer shells, or flexible silicone skins. The increased thickness of the alternative cover 110, as well as the TPE material it is made of, allows it to increase a greater amount of force than other, conventional shells, cases, or covers. The illustrated alternative cover 110 is able to reduce the shock on the electronic device by approximately 43% in a three-foot drop test. It should be appreciated that the actual amount of shock reduction will vary depending on various factors including the material the alternative cover is made of, the thickness of the cover at the point of impact, the shape and size of the impact point. As a result, an electronic device 112 with the alternative cover 110 is able to survive falls that would otherwise disable the electronic device 112. And the alternative cover 110 is relatively light-weight compared to other covers that are able to provide similar shock resisting performance. Additionally, as seen in FIG. 15, the alternative cover 110 has an increased thickness at the corners. This is to provide increased protection if the electronic device 112 is dropped on a corner, since that sort of fall is more likely to damage the electronic device 112.

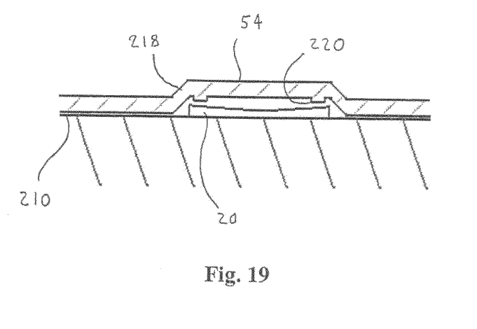

Referring now to FIG. 18, a cross section of an acoustic opening, indicated generally at 210, is shown. The acoustic opening 210 is adapted to be situated adjacent a speaker 212 when the alternative cover 210 is in the installed position and serves to make sound coming from the speaker 212 more clearly audible to the user when the alternative cover 110 is in the installed position. The acoustic opening 210 includes a void 214 located on an inner side 216 of the alternative cover 210. The void 214 provides an air space between the device 112 and alternative cover 210. A plurality of sound channels 216 connects the void 214 with an outer surface 54 of the alternative cover 110.

Referring now to FIG. 19, there is shown a cross-section of a control contour 218. The control contour 218 is adapted to conform to a control 20 on the electronic device 110 when the alternative cover 110 is in the installed position. The control contour 218 is a portion of the alternative cover 110 that is situated over the control 20, serves to accommodate the control 20. The control contour 218 may define a space that allows the alternative cover 110 to be installed on the electronic device 110 without pressing the control 20. This allows the alternative cover 110 to cover and protect the control 20, without unintentional operation of the control 20. However, the resilient nature of the TPE material the alternative cover 110 is made of could make it difficult for the user to operate the control 20 through the alternative cover 110, since it may be difficult to apply sufficient force to the control 20 with a comfortable amount of finger pressure. In order to make it easier for the user to operate the control 20, the control contour includes a narrowed protrusion 220 on the inner side 216 of the alternative cover 110. The narrowed protrusion 220 serves to facilitate operation of the control 20 by the user by focusing force the user applies to the outer surface 54 of the control contour 218 on a smaller area. The illustrated narrowed protrusion 220 is made of the same resilient material as the rest of the alternative cover 110; however, this is not necessary, and the narrowed protrusion 220 may be made of other materials, if desired. It should be appreciated that not all types of controls may be operated through the control contour 218, and that the control contour 218 is most suitable for push-buttons and toggle switches.

The principle and mode of operation of this invention have been explained and illustrated in its preferred embodiments. However, it must be understood that this invention may be practiced otherwise than as specifically explained and illustrated without departing from its spirit or scope.

What is claimed is:

1. A cover comprising:
a back panel structured to substantially cover a back face of an electronic device, the back panel including a friction-reducing treatment on at least a portion of the back panel that will be in contact with the back face when the cover is in an installed position on the electronic device;
a restraining portion that will be disposed against an opposed face of the electronic device when the cover is in the installed position, the restraining portion attached to the back panel by a side member.

2. The cover of claim 1, wherein the friction-reducing treatment comprises a texture on the back panel.

3. The cover of claim 2, wherein the raised texture is made of the same material as the back panel.

4. The cover of claim 3, wherein the back panel, the restraining portion, and the side member are made of the same material.

5. The cover of claim 1, wherein the side member defines four corners.

6. The cover of claim 1, wherein the back panel is made of a thermoplastic elastomer and the friction-reducing treatment comprises a raised texture on the back panel made of the same material as the back panel.

7. A cover assembly comprising:
an electronic device with a screen on a screen side and a back face disposed on the opposed side of the device;
a movable cover, including a hinge bar that is temporarily fixed relative to the electronic device, the movable cover able to be placed into a protective position, wherein it covers the screen, and a use position, wherein it does not cover the screen, the movable cover able to be moved from the protective position to the use position without being detached from the electronic device; and
a stationary cover that is temporarily attached to the electronic device, the stationary cover made of a resilient material and substantially covering the back face of the electronic device, a portion of a bezel on the screen side of the device, and a portion of the hinge bar of the movable cover.

8. The cover assembly of claim 7, wherein the stationary cover includes a raised surface on the screen side of the electronic device wherein the movable cover is in contact with the raised surface and is not in contact with the screen when the movable cover is in the protective position.

9. The cover assembly of claim 7, wherein the stationary cover includes a friction-reducing treatment on at least a portion of the stationary cover in contact with the back face of the electronic device, the friction-reducing treatment comprising a texture made of the same material as the stationary cover.

10. The cover assembly of claim 7, wherein the stationary cover defines hinge openings at opposed ends of the hinge protection.

11. The cover assembly of claim 10, wherein the hinge protection includes a base thickness near the back panel, and a distal thickness at a distal end that is less than the base thickness.

12. The cover assembly of claim 11, wherein the hinge protection is made of the same resilient material as the back panel.

13. The cover assembly of claim 7, the movable cover including an edge lip, and the stationary cover including a raised surface on the screen side of the electronic device;
wherein, when the movable cover is in the protective position, a portion of the movable cover is in contact with the screen of the electronic device, and a portion of the edge lip is in contact with the raised surface of the stationary cover.

14. A cover assembly comprising:
an electronic device with a screen on a screen side and a back face disposed on the opposed side of the device;
a stationary cover that is temporarily attached to the electronic device, the stationary cover made of a resilient material and substantially covering the back face of the electronic device and a portion of a bezel on the screen side of the device.

15. The cover assembly of claim 14, further comprising an acoustic opening defined by the stationary cover, the acoustic opening situated adjacent a speaker on the electronic device and including a void located on an inner side of the stationary cover and at least one sound channel connecting the void with an outer surface of the cover.

16. The cover assembly of claim 15, wherein the acoustic opening includes a plurality of discrete sound channels.

17. The cover assembly of claim 14, wherein the stationary cover has an increased thickness at the corners.

18. The cover assembly of claim 14, further comprising a control contour that includes a space and accommodates a control switch on the electronic device and further includes a narrowed protrusion on an inner side of the stationary cover.

19. The cover assembly of claim 18, wherein the narrowed protrusion is made of the same resilient material as the resilient restraining portion.

20. The cover assembly of claim 14, wherein the portion of the stationary cover that is covering the portion of a bezel on the screen side of the device includes a thickness so that when the cover assembly is placed on a support surface with the screen side facing the support surface, the stationary cover contacts the support surface and there is a space between the screen and the support surface.

21. The cover assembly of claim 14, wherein the stationary cover is able to reduce the shock on the electronic device by at least 40% in a three-foot drop test when compared to the electronic device without the stationary cover.
